(19) United States
(12) Patent Application Publication
(10) Pub. No.: US 2004/0227212 A1
(43) Pub. Date: Nov. 18, 2004

(54) Making contact with the emitter contact of a semiconductor

(76) Inventor: Klaus Goller, Dresden (DE)

Correspondence Address: GERO G. McCLELLAN, MOSER, PATTERSON & SHERIDAN, L.L.P., Suite 1500, 3040 Post Oak Blvd., Houston, TX, 77056, US

(21) Appl. No.: 10/789,384

(22) Filed: Feb. 27, 2004

Related U.S. Application Data
(63) Continuation of application No. PCT/EP02/09346, filed on Aug. 21, 2002.

(30) Foreign Application Priority Data
Aug. 31, 2001 (DE) 101 42 690.9-33

(51) Int. Cl. H01L 21/4763; H01L 23/52; H01L 27/082

(52) U.S. Cl. 257/584; 257/776; 438/619; 257/773; 438/618; 257/587

(57) ABSTRACT

A semiconductor device having contact surfaces of different heights electrically connected to conductors defined on one or more patterned metal planes and a method for fabricating the semiconductor device. In one embodiment, the semiconductor device comprises a substrate having a process surface; a first contact and a second contact arranged on the substrate, a second contact surface of the second contact being at a greater distance, in a substrate-normal direction, from the substrate than a first contact surface of the first contact; a first conductor disposed in a first patterned metal plane and electrically connected to the first contact surface; and a second conductor disposed in a second patterned metal plane and electrically connected to the second contact surface, wherein the second metal plane is disposed at a greater distance, in the substrate-normal direction, from the substrate than the first metal plane.

### CROSS-REFERENCE TO RELATED APPLICATIONS

This application is a continuation of co-pending PCT patent application No. PCT/EP02/09346, filed Aug. 21, 2002, which claims the benefit of German patent application serial number 101 42 690.9-33, filed Aug. 31, 2001. Each of the aforementioned related patent applications is herein incorporated by reference in their entireties.

### BACKGROUND OF THE INVENTION

1. Field of the Invention

The invention relates to a semiconductor device and more particularly, to a semiconductor device having contact surfaces of different heights electrically connected to conductors defined on one or more patterned metal planes and a method for fabricating the semiconductor device.

2. Description of the Related Art

FIG. 16 shows a conventional semiconductor device which will be used to demonstrate the problems of the prior art with which the invention is concerned. The semiconductor device comprises a (vertical) bipolar transistor 10, which, in a known way, has a base contact 12, an emitter contact 14 and a collector contact 16. The bipolar transistor 10 may be an npn transistor or a pnp transistor which, for example, forms part of a radio frequency circuit of the semiconductor device. In addition, a CMOS circuit, which in the simplest case comprises an MOS transistor 20 with a source contact 22, a gate contact 24 and a drain contact 26, may be provided on the same substrate 8 (for example, a silicon wafer).

A characteristic feature of bipolar CMOS circuits-of this type is that the emitter contact (known as the emitter stack) 14 is designed to be significantly “higher” above the process surface 8′ of the substrate 8 than all the other contacts. The contact surface of the emitter contact 14 which is remote from the process surface 8′ of the substrate 8, is at a greater distance from the process surface 8′ than contact surfaces of the other contacts 12, 16, 22, 24 and 26. This relatively greater height of the emitter contact 14 results from necessary process demands imposed on an optimized bipolar transistor.

By way of example, the overall height of the emitter contact 14 of a bipolar transistor corresponding to the Infineon B9C process above the process surface 8′ is typically 550 nm. By contrast, by way of example, the height of the polysilicon gate contact 24 of an MOS transistor 20 arranged on the same substrate 8 is typically only 280 nm.

The very different height of the contact surface of the emitter contact 14, as compared to the other contacts, leads to serious process technology problems with regard to connecting these contacts via contact holes 32 to a first patterned metal plane 34 (known as the metal-1 plane), and these problems are described below.

All the active components of the semiconductor device (i.e., the bipolar and CMOS transistors), after the FEOL (front end of line) process end, are typically covered with a dielectric 30, for example BPSG (Borophosphosilicate glass) to a total height of approximately 1400 nm. FIG. 1 shows a semiconductor device following the step of depositing this insulator layer 30 (BPSG layer). At this stage of the process, the semiconductor device according to the invention is not yet different from the prior art.

Then, the insulator layer 30 is polished back until it is planar with a specified target thickness by means of a chemical mechanical planarization step (CMP BPSG step). The semiconductor device obtained after this polishing step has ended is diagrammatically depicted in FIG. 2.

The high emitter contact 14 means that the planar polishing step (CMP BPSG step) is extremely critical. Whereas in the Infineon C9N process, which is a CMOS logic process belonging to the ninth generation using 0.25 μm technology, this planar polishing step is not a process technology requirement on account of the relatively low height of the gate contact 24 (approximately 280 mm above the substrate surface), transferring the process specification for the C9N CMP BPSG step directly would lead to significant losses of production yield.

For example, in accordance with the C9N process, the insulator layer 30 (the BPSG layer) is polished back to a total height of 700 nm±150 nm in the CMP BPSG polishing step. Therefore, taken as an average over the entire wafer, there is a minimum BPSG layer thickness of 550 nm above the substrate surface, and consequently a BPSG layer 30 with a height of at least 270 nm remains above the gate contact 24. Position-dependent occupation densities of the active components may cause the BPSG layer thickness to locally drop below the typical value of 550 nm. Therefore, the layer heights of the insulator layer 30 achieved for a pure logic-based process in accordance with C9N are not critical, resulting in a relatively wide process window for the CMP BPSG step.

However, if a bipolar transistor 10 is provided as the active component of the semiconductor device (if appropriate in addition to a CMOS transistor 20), the process technology situation is somewhat different. Specifically, if the specification for the step of polishing the insulator layer 30 (CMP BPSG) is transferred direct from the CMOS logic process (Infineon C9N process: BPSG layer height 700 nm±150 nm) to the bipolar CMOS process (Infineon B9C process), the most unfavorable scenario, given an emitter contact height of 550 nm above the substrate 8, may result in a BPSG insulator layer 30 with a height of only a few nanometers. This very thin insulator layer 30 above the emitter contact 14 is not suitable for subsequent patterning of a contact hole 32. Consequently, the process window for the planarization step (CMP BPSG) is greatly reduced with B9C process technology.

Furthermore, it is likely that future bipolar transistor generations, which comprise, in particular, silicon-germanium heterobipolar transistors, will have even higher emitter contacts (emitter stacks) compared to the other contacts (for example the gate contact polystack), which will intensify this problem still further.

A further problem of conventional semiconductor devices which is associated with the relatively high emitter contact 14 is based on the high process engineering demands on the step of patterning the contact holes 32 (CT), via which the contacts 12, 14, 16, 22, 24 and 26 are in each case connected in a standard way to the first patterned metal plane 34. For example, the etching step (CT etch step) for the contact holes 32, which is typically a plasma etching step, has to be highly selective with respect to the emitter contact 14 (polysilicon contact), in order to allow even the “deepest” contact surfaces (i.e., the surfaces located closest to the process surface 8′ of the substrate 8) to be opened up reliably and without residues yet without the emitter contact 14 being attacked. For example, with the abovementioned specifications of the C9N process, source contacts 22 and drain contacts 26 of the MOS transistor 20 may be “buried” a maximum of 850 nm below the insulator layer 30 following the polishing step (CMP BPSG).

To enable these contacts 22 and 26 located close to the substrate to be opened up without leaving any residues by means of the plasma etching step, a relatively long etching time is required. This long etching time, in conjunction with a BPSG layer thickness of 700 nm±150 nm, means that, for a minimum thickness of 550 nm after even a short etching time duration, the etching front of the contact hole 32 which is located above the emitter contact 14 will have reached the contact surface of the emitter contact 14. From this instant onwards, the contact surface of the emitter contact 14 is exposed to the plasma etch. Only if the plasma etching step etches the insulator 30 (e.g., BPSG) highly selectively (through the addition of suitable passivation compounds to the etching plasma) with respect to the contact material (e.g., polysilicon) can the etching process for opening up the deep-lying contact be continued without the emitter contact 14 being attacked. This process engineering requirement may lead to further significant yield losses.

In addition to the process engineering difficulties entailed by the production of the conventional semiconductor device described above (critical process window for the CMP BPSG and CT etch process steps), in known semiconductor devices of this type, the contact surface area of the emitter contact 14 is disadvantageously restricted to the surface area of the contact hole 32. Bipolar applications, which require high emitter-collector current intensities, can only be realized to a limited extent on account of the less than optimum utilization of the cross section of the emitter contact 14.

The problems described above in connection with the fabrication of the known semiconductor device have hitherto been solved by “widening” the specification, derived from the C9N process, for the polishing step (CMP BPSG) carried out on the insulator layer 30. Whereas the C9N process required a specification of 700 nm ±150 nm for the layer height of the insulator layer 30 following the planarization step, the bipolar CMOS process step (Infineon B9C process) only demanded a layer height of the insulator layer 30 of 750 nm±150 nm above the process surface 8′.

If the height of the emitter contact is reduced by 50 nm (i.e., to 500 nm), the process window for the step of etching the contact holes 32 is, as it were, restricted, since there is now a smaller “reserve” of polysilicon of the emitter contact 14 which can be attacked by the contact hole etch (CT etch). This reduces the process window for the plasma etching step for the contact holes 32.

### SUMMARY OF THE INVENTION

In view of the abovementioned drawbacks of conventional semiconductor devices and their production processes, it is an object of the invention to provide a semiconductor device and a process for producing a semiconductor device in which the height of a contact (for example, the emitter contact 14) can be selected as desired without making the processing of the semiconductor device more difficult in the long term.

According to a first aspect of the invention, a semiconductor device comprises

a substrate, the process surface of which has a substrate-normal direction;

at least a first contact and a second contact arranged on the substrate, a contact surface of the second contact being at a greater distance, in the substrate-normal direction, from the substrate than a contact surface of the first contact; and

at least a first and a second patterned metal plane, in each of which at least one conductor, which can be connected to at least one of the contacts, is formed;

the second metal plane being at a greater distance, in the substrate-normal direction, from the substrate than the first metal plane,

the second contact being electrically connected to a conductor, located above it in the substrate-normal direction, of the second metal plane without a conductor of the first metal plane being connected in between, and

the first contact being electrically connected to a conductor, located above it in the substrate-normal direction, of the first metal plane.

As has already been described above, it is customary for all the contacts of the active components of conventional semiconductor devices to be connected, typically via what are known as contact holes (CT), to conductors, located above them in the substrate-normal direction, of a first patterned metal plane. For example, if the active component of the semiconductor device is a bipolar transistor, respective conductors of the first patterned metal plane are connected to the base contact, the emitter contact and the collector contact of the transistor.

However, according to the first aspect of the invention, a different route is taken. According to the invention, a contact whose contact surface is at a great distance from the process surface of the substrate is not connected to a conductor of the first metal plane. Instead, contact is only made with this contact in a subsequent process stage, for example through a contact hole leading to a second patterned metal plane, which is arranged above the first patterned metal plane, as seen in the substrate-normal direction. Consequently, the second contact, which has a considerable height above the process surface compared to the other contacts, can be provided with any desired height, since there is no need to make contact with this second contact together with the other contacts via the first patterned metal plane.

There is no conductor belonging to the first metal plane arranged above the second (high) contact, as seen in the substrate-normal direction. Instead, only a conductor of the second metal plane, which is connected to the contact surface of the second contact, for example, via a tungsten contact pin, is located above the second contact.

With this semiconductor device according to the invention, particular advantages result from the fact that further vertical connecting contacts (known as VIA connecting contacts) are usually provided after processing to connect certain conductors belonging to the first metal plane to higher conductors belonging to the second metal plane. Therefore, contact can be made between the second contact and the second metal plane via the VIA-1 connecting contacts, and consequently, there is no need for any additional lithography, cleaning, metallization and polishing steps in order to make contact with the second contact via the higher metal plane.

According to one embodiment, the second contact is an emitter contact of a bipolar transistor, and the first contact is a base contact or collector contact of a bipolar transistor or a source contact, gate contact or drain contact of an MOS transistor. As described in the introduction, the emitter contact of a bipolar transistor, compared to the other contacts of the active components of a semiconductor device, typically has the greatest height above the process surface of the substrate. It is therefore advantageous for the (relatively high) emitter contact not to be connected to a conductor of the first metal plane, but rather to be connected only to a conductor of the second metal plane, for example via a VIA-1 contact. Therefore, there is no conductor belonging to the first metal plane located above the emitter contact.

The first contact may be connected to the conductor of the first metal plane via a contact hole which extends in the substrate-normal direction and filled with an electrically conductive contact-hole filling material. The contact-hole filling material may, for example, be tungsten which is introduced into a previously plasma-etched contact hole using a MCVD process. A liner, such as a TiN liner, may be provided as a diffusion stop at all the interfaces (in particular between the contact-hole filling material and the metal plane or the contact material).

The second contact may be connected to the conductor of the second metal plane via a contact hole, which extends in the substrate-normal direction and is filled with an electrically conductive contact-hole filling material, without a conductor of the first metal plane being connected in between. As has already been explained above, the contact hole may be what is known as the VIA-1 connecting contact, which normally connects conductors of the second patterned metal plane to corresponding conductors of the first patterned metal plane. According to the invention, this VIA-1 connecting contact can be used to make contact with the second contact or a plurality of high contacts. No conductor of the first metal plane is arranged between the corresponding conductor of the second metal plane and the contact surface of the second contact, as seen in the substrate-normal direction.

According to the first aspect of the invention, a method for fabricating a semiconductor device, in particular a semiconductor device in accordance with the first aspect of the invention, comprises the following steps:

providing a substrate, the process surface of which has a substrate-normal direction;

defining at least a first contact and a second contact on the substrate, a contact surface of the second contact being located at a greater distance, in the substrate-normal direction from the substrate than a contact surface of the first contact;

electrically connecting the first contact to a conductor, located above it in the substrate-normal direction, of a first patterned metal plane; and

electrically connecting the second contact to a conductor, located above it in the substrate-normal direction, of a second patterned metal plane without a conductor of the first metal plane being connected in between;

the second metal plane being at a greater distance, in the substrate-normal direction, from the substrate than the first metal plane.

Accordingly, in a method for fabricating a semiconductor device in accordance with the first aspect of the invention, the second contact, which is further away from the process surface as seen in the substrate-normal direction, is not connected to a conductor of the first metal plane, but rather is connected only to a conductor, located above it in the substrate-normal direction, of the second metal plane.

This simplifies the patterning of the electrical connections for the other contacts to form the first patterned metal plane to a considerable extent. This is because there is no need to take into account the (high) second contact or a multiplicity of such high second contacts when realizing the process engineering for electrically connecting the first contact to the first metal plane. Instead, the patterning and process parameters for making contact with the first contact (or first contacts) can be optimized for this contact-making step. At the same time, the height of the second contact (i.e., the distance from the top of the second contact to the process surface, as seen in the direction normal to the substrate) can be selected as desired (provided that the BPSG layer thickness is adapted at the same time; its minimum height must be greater than or equal to the resulting contact height of the second contact), in order to ensure optimum patterning and component properties.

The second contact may be an emitter contact of a bipolar transistor, and the first contact may be a base contact or collector contact of a bipolar transistor or a source contact, gate contact or drain contact of an MOS transistor.

The step of electrically connecting the first contact may comprise the following steps:

defining a contact hole, which ends at the first contact and extends in the substrate-normal direction, in an insulator;

filling the contact hole with an electrically conductive contact-hole filling material; and

defining the conductor, which lies above the first contact in the substrate-normal direction, of the first metal plane in such a manner that it is electrically connected to the contact-hole filling material.

By way of example, after the active components of the semiconductor device has been completed (FEOL process end), a dielectric insulator, such as BPSG (borophosphosilicate glass) is deposited on the semiconductor device by means of a CVD process, polished back to a target height by means of a subsequent planarization step (CMP BPSG) and patterned by means of conventional lithography and etching steps. The contact hole which is formed and extends along the substrate-normal direction ends at the first contact with which contacts is to be made or the first contacts with which contacts are to be made. This contact hole may then be filled with an electrically conductive contact-hole filling material, such as tungsten, by means of a MCVD metallization step. Then, a conductor of the first metal plane may be arranged on the tungsten contact pin, which has been planarized again, in such a manner that the conductor is electrically and conductively connected to the first contact.

The step of electrically connecting the second contact may comprise the following steps:

defining a contact hole, which ends at the second contact and extends in the substrate-normal direction, in an insulator;

filling the contact hole with an electrically conductive contact-hole filling material; and

defining the conductor, which lies above the second contact in the substrate-normal direction, of the second metal plane in such a manner that it is electrically connected to the contact-hole filling material without a conductor of the first metal plane being connected in between.

At the same time as the step of electrically connecting the second contact to the conductor of the second metal plane, at least one conductor of the first metal plane may be connected to a conductor of the second metal plane. Accordingly, the second contact may be electrically and conductively connected to a conductor of the second metal plane via what is known as the VIA-1 connecting contact. The processing of these VIA-1 connecting contacts forms part of the standard processes carried out on semiconductor devices of this type, and consequently, there is no need for any additional patterning steps to make contact with the second contact compared to conventional processes.

According to a second aspect of the invention, a semiconductor device comprises

a substrate, the process surface of which has a substrate-normal direction;

at least a first contact and a second contact arranged on the substrate, a contact surface of the second contact being at a greater distance, in the substrate-normal direction, from the substrate than a contact surface of the first contact; and

at least one patterned metal plane, in which at least a first conductor and a second conductor are formed, each of which can be connected to one of the contacts;

the first contact being electrically connected to the first conductor, located above it in the substrate-normal direction, of the metal plane (340) via a contact hole, which extends in the substrate-normal direction and is filled with an electrically conductive contact-hole filling material, and

the second contact directly adjoining the second conductor, located above it in the substrate-normal direction, of the metal plane, so that the second contact is electrically connected to the second conductor without a filled contact hole being connected in between.

According to the second aspect of the invention, the second contact (i.e., the higher contact) is not electrically connected to a conductor of the metal plane (e.g., first metal plane) via a contact hole. Instead, the electrical connection is effected directly without an electrical contact hole being connected in between by virtue of the second conductor of the metal plane adjoining the contact surface of the second contact. Consequently, the processing of the contact holes for the other contacts can be carried out without taking account of the high second contact, which means that the patterning of the contact holes for connecting the first contact to the metal plane is not critical compared to the conventional semiconductor device as described in the introduction.

The contact surface of the second contact is not opened up by a plasma etching step of a contact hole, but rather may be opened up by a polishing step (CMP step). Consequently, the height of the second contact can be selected as desired or matched to the process requirements of an optimized active component.

The second contact may be an emitter contact of a bipolar transistor, and the first contact may be a base contact or collector contact or a source contact, gate contact or drain contact of an MOS transistor.

According to the second aspect of the invention, a method for fabricating a semiconductor device comprises the following steps:

providing a substrate, the process surface of which has a substrate-normal direction;

defining at least a first contact and a second contact on the substrate, with a contact surface of the second contact being at a greater distance, in the substrate-normal direction, from the substrate than a contact surface of the first contact;

electrically connecting the first contact to a first conductor, located above it in the substrate-normal direction, of a patterned metal plane by means of a contact hole, which extends in the substrate-normal direction and is filled with electrically conductive contact-hole filling material; and

electrically connecting the second contact to a second conductor, which is located above it in the substrate-normal direction and adjoins the second contact, of the metal plane without a filled contact hole being connected in between.

Consequently, the first contact or first contacts, as is also the case with typical known fabrication methods, is connected to corresponding conductors of the patterned metal plane via contact holes extending in the substrate-normal direction. The contact holes are defined, for example, in an insulator, in particular BPSG, by means of a lithography and subsequent plasma etching step, which is followed by a metallization step for filling the contact hole with a contact-hole filling material such as tungsten. Then, the first conductor of the metal plane is defined on the polished top side, remote from the process surface, of this vertical contact pin, which ends at the contact surface of the first contact, in such a manner that this first conductor is electrically connected to the contact-hole filling material.

By contrast, the electrical connection of the second contact to a second conductor of the patterned metal plane takes place in a different way. In this case, a contact hole filled with contact-hole filling material is not used, i.e., the vertical contact pin is absent. Instead, the contact surface of the second contact directly adjoins the corresponding conductor of the metal plane, so that there is an electrical connection between the conductor of the (first) metal plane and the second contact. However, it is possible for a thin liner layer, in particular as a diffusion stop (e.g., comprising TiN), to be present between the contact surface of the second contact and the second conductors of the patterned metal plane.

On account of the fact that contact between the contact surface and the second contact is not made by means of a contact hole together with the first contact or contacts, the process demands imposed on the patterning of the contact hole are significantly looser. The normal height of the second contact can now be selected as desired, independently of the process restrictions of the contact hole patterning.

The second contact may be an emitter contact of a bipolar transistor, and the first contact may be a base contact or collector contact of a bipolar transistor or is a source contact, gate contact or drain contact of an MOS transistor.

The step of electrically connecting the first contact may comprise the following steps:

defining a contact hole, which ends at the first contact and extends in the substrate-normal direction, in an insulator;

filling the contact hole with an electrically conductive contact-hole filling material; and

defining the first conductor, which is located above the first contact as seen in the substrate-normal direction, of the metal plane in such a manner that it is electrically connected to the contact-hole filling material.

The step of electrically connecting the second contact may comprise the following steps:

defining an uncovered contact surface, which is oriented in the substrate-normal direction, of the second contact by means of a planar polishing step; and

defining the second conductor of the metal plane in such a manner that it adjoins the uncovered contact surface of the second contact in an electrically conductive manner.

The contact surface of the second contact may be opened up by means of a planar polishing step, rather than by a plasma etching step as in the case of the first contact. In this context, known CMP polishing steps are particularly suitable. By way of example, after the CVD deposition of the insulator (for example, BPSG) after the FEOL process end, the planar polishing step for polishing back the insulator (e.g., BPSG) is carried out in such a manner that the target height of the insulator is such that the polishing step ends at the second contact.

Known endpoint detection systems may be used to set the endpoint of the CMP polishing step. The second contact itself may be used as a polishing stop in the polishing or planarization step. It is also possible to provide additional structures which are used as a polishing stop.

Since the previously uncovered contact surface of the second contact is protected by a photoresist during the lithography and plasma etching step of the contact hole for making contact with the first contact, the contact surface of the second contact is not attacked during the plasma etching step. Therefore, electrical contact may be easily made with the uncovered contact surface of the second contact by the second conductor of the metal plane being applied to this contact surface. It may be advantageous for a liner (for example, TiN), which functions as a migration stop, to be sputtered on prior to definition of the second conductor of the metal plane (for example, an AICu plane which has been applied using a MCVD process and then patterned).

As an alternative to uncovering the contact surface of the second contact by means of a polishing step carried out on the insulator (for example, BPSG), this contact surface may be uncovered by means of a subsequent polishing step carried out on the contact-hole filling material.

### BRIEF DESCRIPTION OF THE DRAWINGS

The invention is described below by way of example with reference to accompanying drawings showing preferred embodiments, in which:

FIGS. 1 to 14 show diagrammatic sectional views through one embodiment of a semiconductor device in accordance with the first aspect of the invention at various patterning or processing stages during the fabrication method;

FIG. 15 shows a diagrammatic sectional view through another embodiment of a semiconductor device in accordance with the second aspect of the invention; and

FIG. 16 shows a sectional view through a conventional semiconductor device.

### DETAILED DESCRIPTION OF THE PREFERRED EMBODIMENT

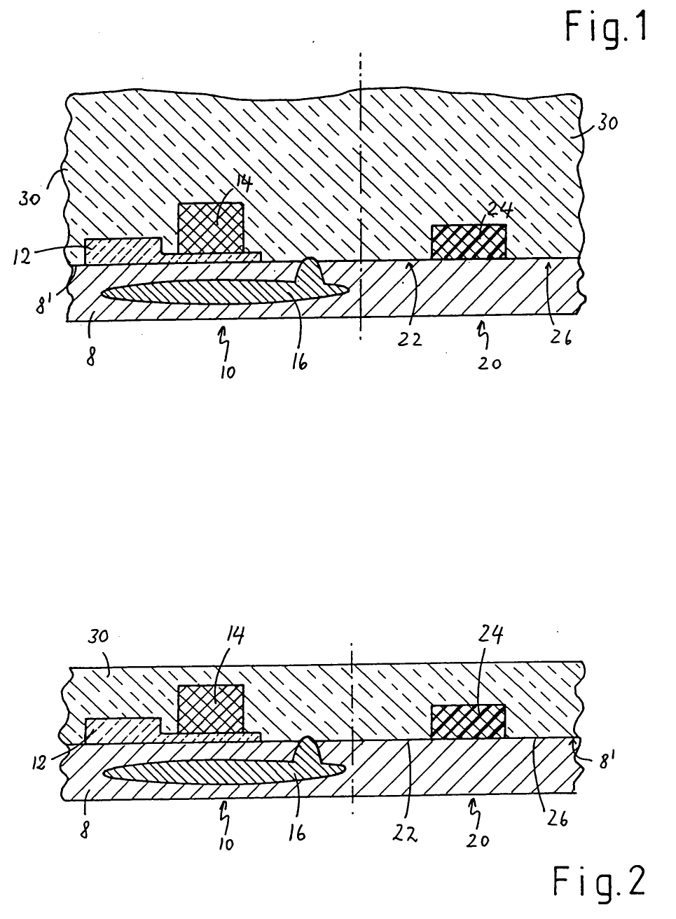

FIG. 1 shows a sectional view through one embodiment of a semiconductor device in accordance with the first aspect of the invention. The semiconductor device is at a process stage in which portions of the active components, such as the bipolar transistor 10 and the MOS transistor 20, have already been completed. The FEOL (front end of line) process end, in which in particular high-temperature steps may occur, has therefore already been reached.

As shown in FIG. 1, in the following process step, the entire semiconductor device is covered with a dielectric insulator 30, which may, for example, be BPSG (borophosphosilicate glass), by means of a CVD deposition step (CVD BPSG step). The insulator layer 30 is typically applied in a layer height of about 1400 nm. This layer covering is significantly greater than the height of the emitter contact 14, which is typically at about 550 nm, and of the gate contact 24, which is typically at about 280 nm.

In a following process step, as illustrated in FIG. 2, the insulator layer 30 is polished back by a polishing step to a target height of typically about 700 nm±150 nm, in which commonly known CMP (chemical mechanical planarization) steps may be used (CMP BPSG step).

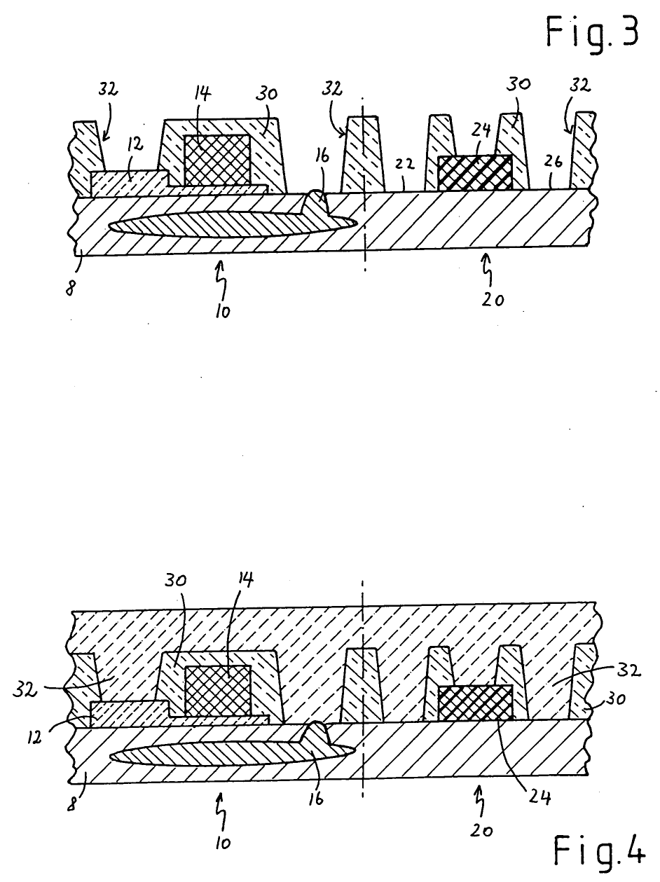

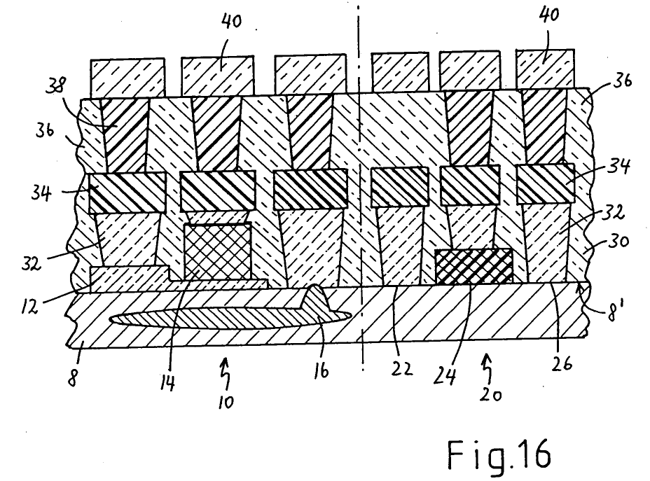

As illustrated in FIG. 3, contact holes 32 are then defined in the insulator layer 30 by means of a lithography and subsequent etching step (CT etch step). These contact holes 32 extend in the direction normal to the substrate 8, i.e. they have a vertical orientation. Unlike in a conventional fabrication method, for example for a semiconductor device as illustrated in FIG. 16, a contact hole 32 which ends at a contact surface of the emitter contact 14 is not defined. In other words, a window leading to the contact surface of the emitter contact 14 is not etched into the insulator layer 30.

Therefore, during the immediately subsequent metallization step, contact is not made with the emitter contact 14, which in this embodiment of the semiconductor device is referred to as the second (higher) contact. On account of the fact that contact is not made with the emitter contact 14 (the second contact) at this process stage, the patterning of the contact holes 33, i.e., the CMP BPSG polishing step and the CT etch plasma etching step, does not need to be adapted to make simultaneous contact with the first and second contacts, which is complex in terms of the process engineering.

As a result, the process window for the CMP BPSG polishing step, the result of which is illustrated in FIG. 2, and for the CT etch plasma etching step (cf. FIG. 3) is widened considerably compared to a conventional method for fabricating the semiconductor device shown in FIG. 16. The permissible height in the substrate-normal direction for the second contact (i.e., emitter contact 14) no longer has to be critically selected while taking account of the patterning of the contact holes 32. Instead, in accordance with the fabrication method according to the invention for a semiconductor device in accordance with the first aspect of the invention, the height of the emitter contact 14 can be selected freely or matched to the process requirements of an optimized bipolar transistor. Eliminating the topology-induced restrictions on the height of the emitter contact 14 makes it possible to avoid the need to develop new contact hole etching techniques for bipolar components belonging to future technology platforms.

FIG. 4 illustrates one embodiment of the semiconductor device according to the invention in accordance with the first aspect of the invention after the contact hole metallization has concluded. To begin in metallization of the contact holes, a liner, which consists, for example, of TiN and is used in particular as a diffusion stop, may be sputtered. Then, a metal, such as tungsten, is deposited, filling the contact holes 32 as a contact-hole filling material, for example, by means of a MCVD process.

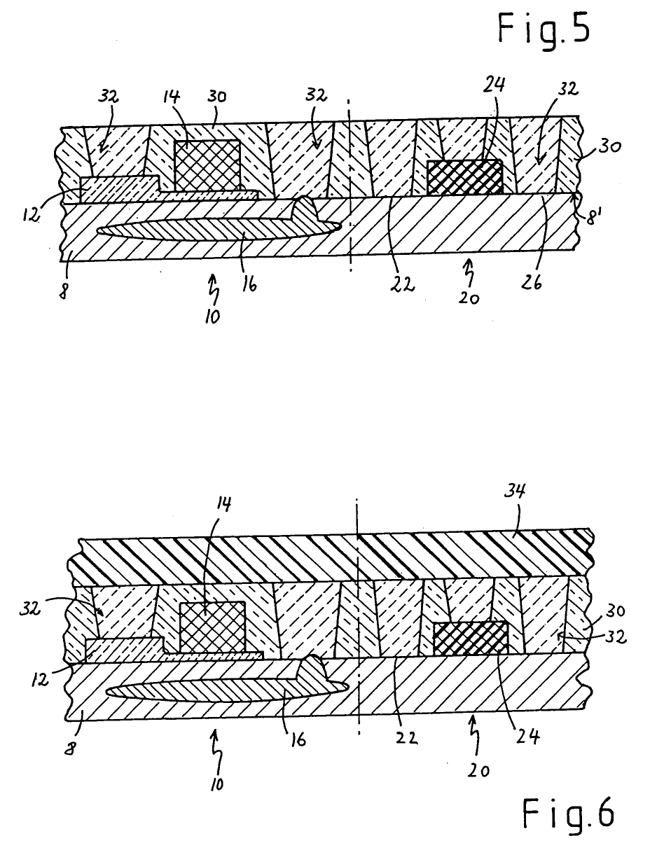

The process steps illustrated in FIGS. 4 to 9 correspond to steps used in a conventional method for fabricating a semiconductor device as illustrated, for example, in FIG. 16. Therefore, in a conventional way, the electrically conductive contact-hole filling material is polished back to a target height by means of a planarization step (step: CMP W). The target height in this case is selected in such a manner that the emitter contact 14 (the second contact) is not opened up (as shown in FIG. 5), and there are no residues of the filling material or liner outside the defined contact holes 32.

Then, to form the first patterned metal plane 34, a metal, which may, for example, be AICu, is sputtered onto the semiconductor device (as shown in FIG. 6; step: sputter metal 1). The layer thickness of this first metal plane 34 may be selected as a function of the design requirements and is typically about 400 nm.

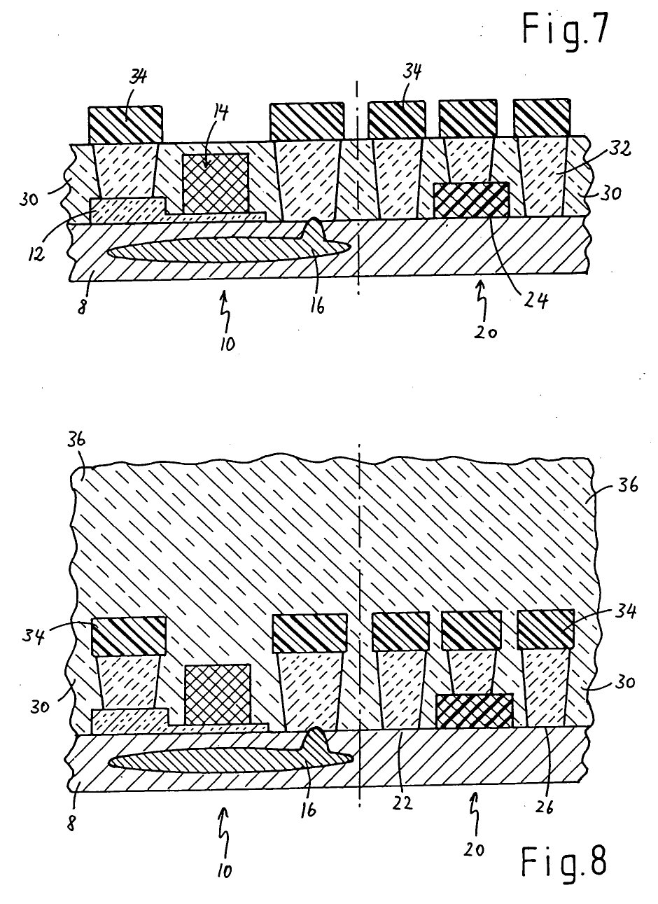

A subsequent lithography and etching step (step: etch metal 1) is used to pattern the first metal plane 34 in such a manner that electrical conductors or connection contacts are formed in the first metal plane 34 above the contact holes 32, which are filled, for example, with tungsten. As illustrated in FIG. 7, all the (first) contacts 12, 16, 22, 24 and 26 are connected via contact holes to corresponding conductors, located above them in the substrate-normal direction, of the first metal plane 34. However, above the second contact 14, which in one embodiment is the emitter contact, there is no conductor (e.g., etched away) of the first metal plane 34 arranged above the contact 14 in the substrate-normal direction.

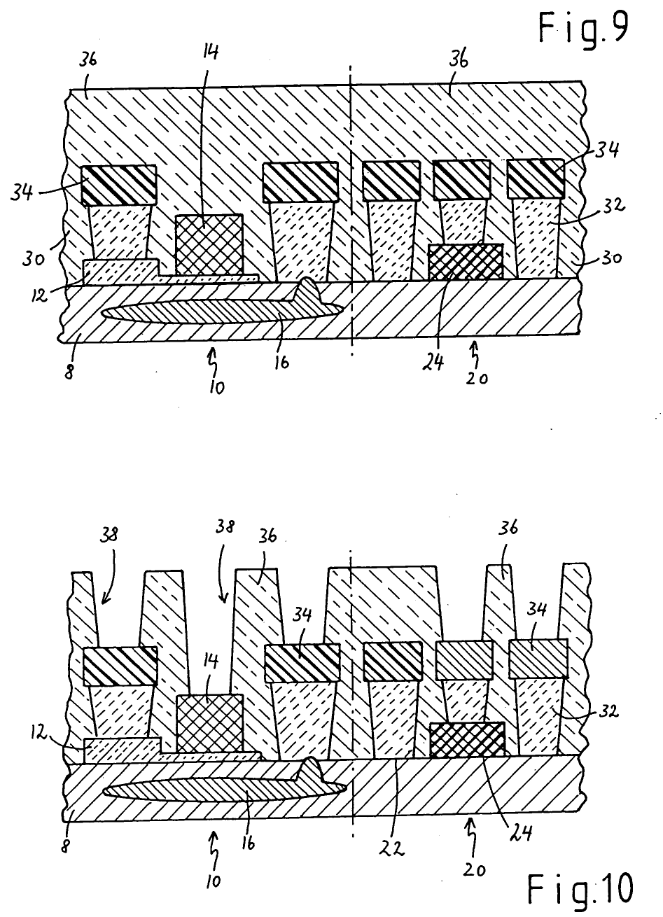

This is followed, in a deposition step, by the application of a further dielectric or insulator (step: deposit ILD1 (interlayer dielectric 1)). FIG. 8 shows the semiconductor device after this deposition step has been completed. Then, the dielectric layer 36, which has previously been deposited, is polished back to a target height by means of a further polishing step (step: CMP ILD1) (as shown in FIG. 9).

Next, in the same way as for the step of patterning the insulator layer 30 explained with reference to FIG. 3, a lithography and etching step is used to introduce contact holes 38 into the dielectric 36 (ILD) (step: etch VIA1). Unlike in a conventional fabrication method, for example, for a semiconductor device as shown in FIG. 16, however, not only the contact holes 38 which end at conductors of the first metal plane 34, but also a contact hole 38 which ends at the contact surface of the emitter contact 14 (i.e., the second contact) are patterned (as shown in FIG. 10).

A window leading to the emitter contact 14 is therefore opened up during the patterning of what are known as the VIA-1 connecting channels, which are standard means of connecting conductors of the first metal plane 34 to conductors of the second metal plane 40. Consequently, unlike in the prior art, contact is made with the emitter contact 14 through a VIA1 contact hole connection to the second metallization plane.

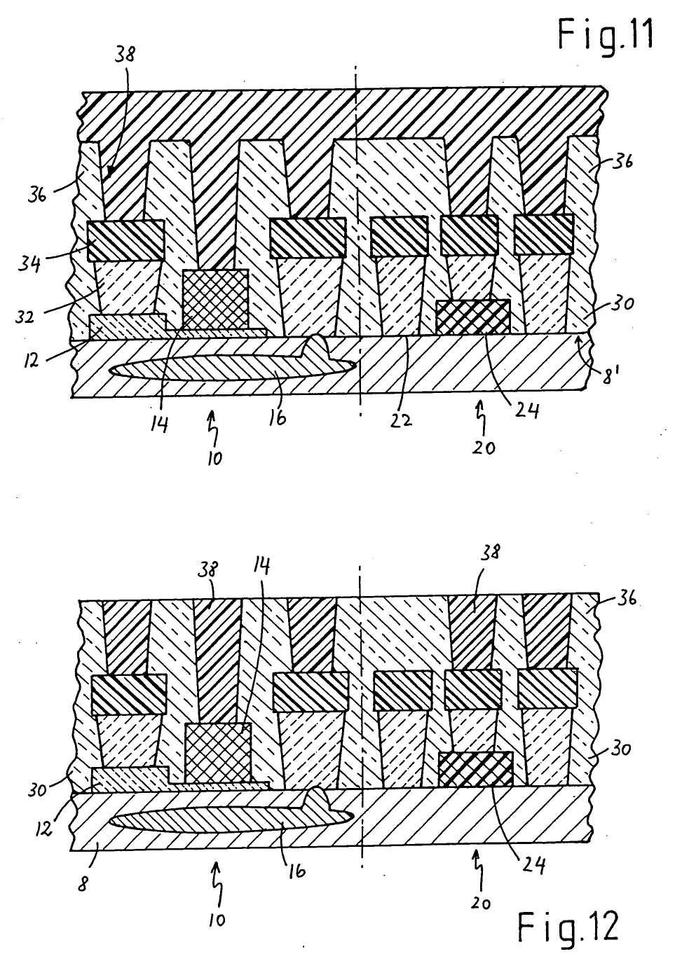

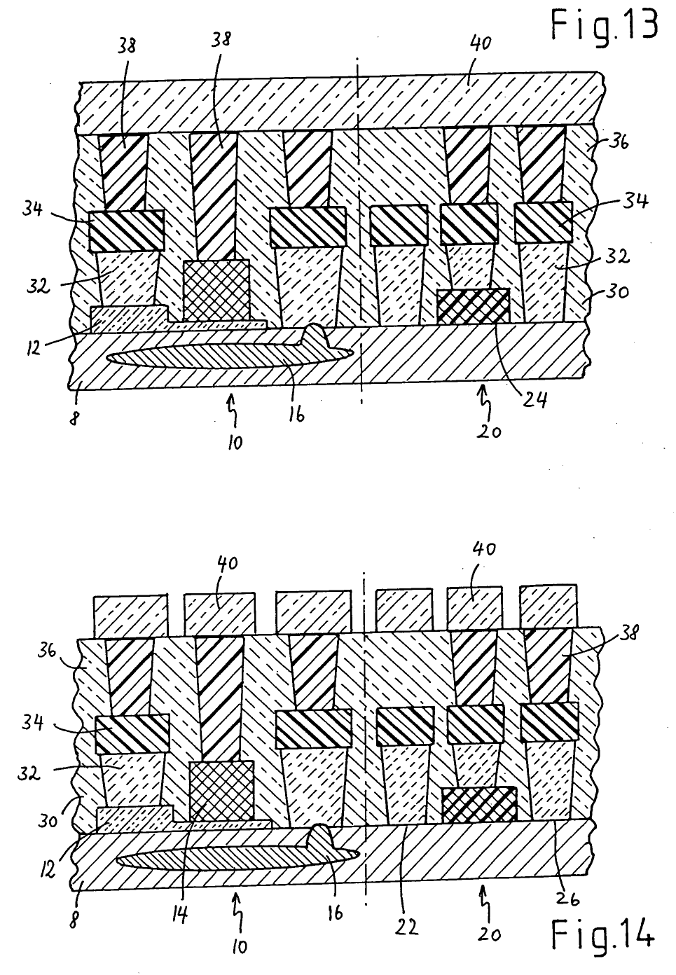

Then, in a similar way to the metallization step described with reference to FIG. 4, the contact holes 38 are filled with an electrically conductive contact-filling material. First, a liner (TiN) is sputtered on as a diffusion stop (step: sputter liner). Next, a suitable metal (for example, tungsten) is deposited by means of a MCVD process (step MCVD W; as shown in FIG. 11), and this metal is polished back to a target height by means of a further planar polishing step (step: CMP W; as shown in FIG. 12). The second metal plane 40 is deposited (as shown in FIG. 13) and patterned (as shown in FIG. 14) in the same way as the patterning of the first metal plane 34 which was described with reference to FIGS. 6 and 7.

FIG. 14 illustrates one embodiment of the semiconductor device in accordance with the first aspect of the invention after the method steps of the invention have been completed. As explained in detail above, this semiconductor device differs from a known semiconductor device illustrated in FIG. 16, in particular, through the fact that the second contact 14 (in this embodiment, the emitter contact) is not connected to a conductor of the first metal plane 34 by means of a filled contact hole 32, but rather is directly connected to the second metallization plane 40, through what is known as the VIA-1 connecting contact. There is no conductor belonging to the first metal plane 34 arranged between the contact surface of the second contact 14 and the conductor of the second metallization plane 40, which is arranged above the contact 14 in the substrate-normal direction.

Since the so-called VIA-1 connecting contact, which is a standard means of connecting conductors of the first metal plane to conductors of the second metal plane, is formed in a standard process, making contact with the second contact 14 to the second metal plane 40, as described in one embodiment of the invention, does not entail additional process steps. Accordingly, the VIA-1 etching above the contact 14 is not stopped by a conductor of the first metal plane, (i.e., conductor does not exist at this location) but rather ends at the polysilicon of the emitter contact 14. Therefore, the liners which can be used as an etching stop are broken through into the first metal plane 34 or the polysilicon of the emitter contact 14 in a simultaneous, controlled manner.

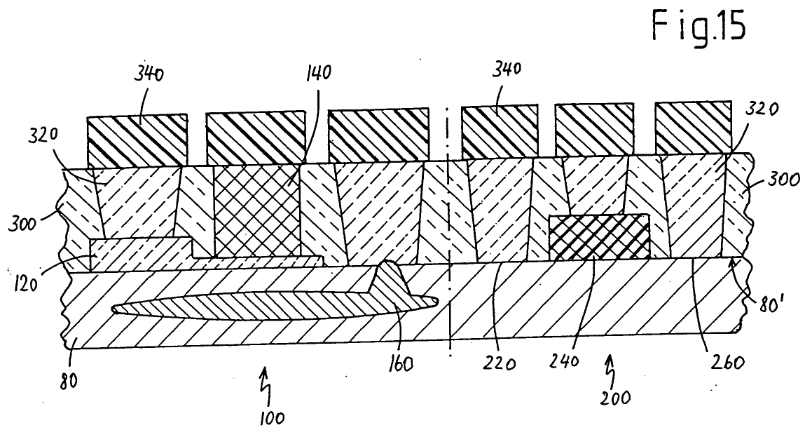

FIG. 15 shows a semiconductor device, in accordance with a second aspect of the invention, after the fabrication method steps of the invention have been completed. The semiconductor device has a substrate 80, which may be a silicon semiconductor substrate, with a process surface 80′. The active components which have been patterned in the FEOL process steps may, for example, correspond to those of the embodiments of the semiconductor device in accordance with the first aspect of the invention which has been described above.

In the embodiment illustrated in FIG. 15, components of a bipolar transistor 100 are shown with a base contact 120 (first contact), an emitter contact 140, which forms the second (higher) contact, and a collector contact 160 (first contact). The bipolar transistor 100 may, for example, be part of a radio frequency circuit of the semiconductor device. Furthermore, the embodiment of the semiconductor device illustrated in FIG. 15 may include a CMOS circuit, which is represented in simplified form by a MOS transistor 200. The MOS transistor 200 comprises a source contact 220, a gate contact 240 consisting of polysilicon and a drain contact 260. The contacts 220, 240 and 260 are first contacts in the sense of the embodiments of the invention.

As described in connection with FIG. 1, after the FEOL process has been completed, the semiconductor device is covered with an insulator 300, which may be, for example, BPSG (borophosphosilicate glass), by means of a CVD deposition process.

Unlike in the fabrication method in accordance with the first aspect of the invention and known fabrication methods, however, the subsequent planar polishing step (step: CMD BPSG) is carried out in such a manner that the insulator is polished back as far as the second contact (i.e., the emitter contact 140). The CMP process step is therefore stopped at the contact surface of the emitter contact 140. An end point detection system, as commonly known, which indicates the instant at which the polishing step reaches the second contact 140, may be used for this purpose. It is also possible to provide additional auxiliary structures which function as a polishing stop.

As described in detail with reference to FIGS. 3 to 5, contact holes 320 are then patterned in the insulator 300 by means of a lithography step and an etching step (step: CT etch). However, unlike in the case of a conventional semiconductor device as shown in FIG. 16, a contact hole 320 is not formed above the emitter contact 140. The contact holes 320 can be lined in typical ways with a liner (for example, TiN) and filled with a suitable contact-hole filling material, such as tungsten. The metal layer which has been applied, for example, using a MCVD process is polished back, in a subsequent planar polishing step (CMP W), to a target height which may be the height of the contact surface of the emitter contact 140 (of the second contact). The step of polishing the contact-hole filling material of the contact holes 320 may also be used to open up (and eliminate liner residues from) the contact surface of the second contact 140.

This is followed by definition of the patterned metal plane 340, the process steps of which are no different from a conventional standard process for defining metal planes of this type. It should be noted that a conductor of the metal plane 340, which is arranged above the second contact 140 in the substrate-normal direction, directly adjoins this second contact, so that an electrically conductive connection is produced between the second contact 140 (the emitter contact) and the corresponding conductor of the metal plane 340. In other words, the second contact 140, unlike the other contacts of the semiconductor device, is not connected to the associated conductor of the metal plane 340 by a contact-hole pin. Instead, contact is made with the second contact 140 directly by a conductor of the first metal plane 340 which adjoins the second contact 140. A thin, metallic interlayer may be provided between the second contact 140 and a conductor of the metal plane 340, for example, to reduce the contact resistance.

An advantage of this fabrication method and/or of the semiconductor device which is thereby obtained is that the height of the second contact 140 may be selected as desired in the substrate-normal direction and/or may be matched to the process requirements of an optimized bipolar transistor. There is no need for thickness measurement by means of STI. At the same time, the uncertainty in the measurement of the layer thickness of the insulator 300 (the BPSG layer) following the CMP BPSG polishing step (which amounts to ±150 nm) is reduced, and the risk of over-polishing is minimized or eliminated. There is no need to make contact with the second contact by means of a contact hole 320 filled with contact-hole filling material (for example tungsten). The first metal plane 340 can be connected to the emitter contact 140 directly (without the need for contact hole pins 320).

The limitation of the contact surface area, i.e., the diameter of the contact holes 320, is eliminated, since the entire effective surface area of the second contact 140 can be used to produce a contact. This means that higher current intensities can be realized in the bipolar transistor 100 and/or optimally matched to the surface area of the emitter contact 140.

What is claimed is:

1. A semiconductor device, comprising:
a substrate having a process surface;
a first contact and a second contact arranged on the substrate, a second contact surface of the second contact being at a greater distance, in a substrate-normal direction, from the substrate than a first contact surface of the first contact;
a first conductor disposed in a first patterned metal plane and electrically connected to the first contact surface; and
a second conductor disposed in a second patterned metal plane and electrically connected to the second contact surface; wherein the second metal plane is disposed at a greater distance, in the substrate-normal direction, from the substrate than the first metal plane.

2. The semiconductor device of claim 1, wherein the second contact is an emitter contact of a bipolar transistor, and the first contact is one of a base contact and a collector contact of the bipolar transistor, or one of a source contact, a gate contact, and a drain contact of a MOS transistor.

3. The semiconductor device of claim 1, wherein the first contact is connected to the conductor of the first metal plane via a first contact hole which extends in the substrate-normal direction and is filled with an electrically conductive contact-hole filling material.

4. The semiconductor device of claim 3, wherein the second contact is connected to the second conductor of the second metal plane via a second contact hole, which extends in the substrate-normal direction and is filled with an electrically conductive contact-hole filling material.

5. A method for fabricating a semiconductor device, comprising:
providing a substrate, having a process surface;
defining a first contact and a second contact on the substrate, a second contact surface of the second contact being located at a greater distance, in a substrate-normal direction from the substrate than a first contact surface of the first contact;
electrically connecting the first contact to a first conductor, of a first patterned metal plane; and
electrically connecting the second contact to a second conductor of a second patterned metal plane, wherein the second metal plane is disposed at a greater distance, in the substrate-normal direction, from the substrate than the first metal plane.

6. The method of claim 5, wherein the second contact is an emitter contact of a bipolar transistor, and the first contact is one of a base contact and a collector contact of the bipolar transistor, or one of a source contact, a gate contact, and a drain contact of a MOS transistor.

7. The method of claim 5, wherein electrically connecting the first contact comprises:
defining a first contact hole, which ends at the first contact surface and extends in the substrate-normal direction, in an insulator;
filling the contact hole with an electrically conductive contact-hole filling material; and
defining the first conductor of the first metal plane disposed above the first contact in the substrate-normal direction to electrically connect to the contact-hole filling material.

8. The method of claim 7, wherein electrically connecting the second contact comprises:
defining a second contact hole, which ends at the second contact surface and extends in the substrate-normal direction, in an insulator;
filling the contact hole with an electrically conductive contact-hole filling material; and
defining the second conductor of the second metal plane disposed above the second contact in the substrate-normal direction to electrically connect to the contact-hole filling material.

9. The method of claim 5, wherein during a process for electrically connecting the second contact to the conductor of the second metal plane, at least one other conductor of the first metal plane is electrically connected to another conductor of the second metal plane.

10. A semiconductor device, having
a substrate having a process surface;
a first contact and a second contact arranged on the substrate, a second contact surface of the second contact being at a greater distance, in the substrate-normal direction, from the substrate than a first contact surface of the first contact; and
a patterned metal plane wherein a first conductor and a second conductor are formed; wherein the first contact is electrically connected to the first conductor of the patterned metal plane via a contact hole, which extends in the substrate-normal direction and is filled with an electrically conductive contact-hole filling material, and wherein the second contact directly adjoins the second conductor of the patterned metal plane.

11. The semiconductor device of claim 10, wherein the second contact is an emitter contact of a bipolar transistor, and the first contact is one of a base contact and a collector contact of the bipolar transistor, or one of a source contact, a gate contact, and a drain contact of a MOS transistor.

12. A method for fabricating a semiconductor device, comprising:
providing a substrate having a process;
defining a first contact and a second contact on the substrate, with a second contact surface of the second being at greater distance, in the substrate-normal direction, from the substrate than a first contact surface of the first contact;
electrically connecting the first contact to a first conductor of a patterned metal plane through a contact hole, which extends in the substrate-normal direction and is filled with electrically conductive contact-hole filling material; and
electrically connecting and adjoining the second contact to a second conductor of the patterned metal plane.

13. The method of claim 12, wherein the second contact is an emitter contact of a bipolar transistor, and the first contact is one of a base contact and a collector contact of the bipolar transistor, or one of a source contact, a gate contact, and a drain contact of a MOS transistor.

14. The method of claim 12, wherein electrically connecting the first contact comprises:
defining a first contact hole, which ends at the first contact and extends in the substrate-normal direction, in an insulator;
filling the first contact hole with an electrically conductive contact-hole filling material; and
defining the first conductor of the patterned metal plane to electrically connect to the contact-hole filling material.

15. The method of claims 12, wherein electrically connecting the second contact comprises:
defining the second contact surface, which is oriented in the substrate-normal direction, of the second contact utilizing a planar polishing step (CMP BPSG, CMP W); and
defining the second conductor of the patterned metal plane to adjoin the second contact surface of the second contact in an electrically conductive manner.
